(19) United States
(12) Patent Application Publication
(10) Pub. No.: US 2023/0154833 A1
(43) Pub. Date: May 18, 2023

(54) MODULE PACKAGE WITH COAXIAL LEAD ASSEMBLY

(71) Applicant: Qorvo US, Inc., Greensboro, NC (US)

(72) Inventors: Michael Roberg, Evergreen, CO (US); Scott Schafer, Denver, CO (US); Terry Hon, Saint Paul, TX (US)

(21) Appl. No.: 17/987,090

(22) Filed: Nov. 15, 2022

Related U.S. Application Data
(60) Provisional application No. 63/280,030, filed on Nov. 16, 2021.

(51) Int. Cl. H01L 23/495; H05K 1/18

(52) U.S. Cl. CPC H01L 23/49517; H01L 23/4952; H01L 23/49527; H05K 1/182; H01L 24/48; H01L 2224/48225

(57) ABSTRACT

A module package in which electronic components are packaged. The package module may comprise a base, at least one component, a housing, and a coaxial lead assembly. The component is over the base. The housing is over the base and encompasses the component. The coaxial lead assembly extends out of the housing and facilitates electrical connections with the component. The at least one coaxial lead assembly comprises a dielectric structure, a central conductor, and an outer conductor formed by a top wall extending between two side walls. The central conductor may be between the two side walls. The dielectric structure may reside between the central conductor and the outer conductor, such that the central conductor and outer conductor are isolated from one another.

### RELATED APPLICATIONS

This application claims the benefit of provisional patent application serial number 63/280,030, filed Nov. 16, 2021, the disclosure of which is hereby incorporated herein by reference in its entirety.

### FIELD OF THE DISCLOSURE

The present disclosure relates to a module package in which electronic components are packaged.

### BACKGROUND

Module packages are used in many radio frequency (RF) communication systems. The module packages often perform a specific function and are mounted to a printed circuit board (PCB). The baseline module package platform has some challenges associated with it which limit performance. First and foremost is the bandwidth and acceptable operating frequency. The RF leads of the module package are, by nature, mostly inductive. The resultant inductance can best be described as a parasitic, which must be dealt with rather than a desired transition. The inductive nature of the leads restricts both the operating frequency that the module package may be used at as well as the bandwidth over which an acceptable package transition can be realized. To make matters worse, the inductance varies substantially based upon the gap between the package and where the leads land on the PCB. Presence of the gap is an unavoidable issue due to mechanical tolerances. The distance over which the lead is fully in air can vary by multiple mils based on how the package is placed and bolted down within the assembly. As this distance varies, so will the associated parasitic inductances.

Another issue with module package is the RF power handling of the package. On the module package side, the leads are landed on an organic substrate, which has limited thermal conductivity (e.g. less than 2 W/(m*K)). As frequency and RF power increase, additional power is dissipated. At a certain point, metal traces on the organic substrate will delaminate, which leads to long-term reliability issues. In the short term, the traces can get so hot that the solder on the PCB side where the leads are attached actually reflows (i.e. liquifies). Solder reflow inevitably causes a catastrophic failure of the components within the module package. Much of the issue is related to the fact that a portion of the RF lead is sitting in air, bridging the gap between the module package and the PCB. In this case, there are only two heat transfer mechanisms. The heat must conduct along the lead or use convection around the lead to move the heat away. However, the gap is generally filled only with air, and air is a poor conductor of heat. As such, there is a need for a way to enhance RF performance and/or provide better heat transfer for module packages.

### SUMMARY

The present disclosure relates to a module package in which electronic components are packaged. The package module may comprise a base, at least one component, a housing, and a coaxial lead assembly. The component is over the base. The housing is over the base and encompasses the component. The coaxial lead assembly extends out of the housing and facilitates electrical connections with the component. The at least one coaxial lead assembly comprises a dielectric structure, a central conductor, and an outer conductor formed by a top wall extending between two side walls. The central conductor may be between the two side walls. The dielectric structure may reside between the central conductor and the outer conductor, such that the central conductor and outer conductor are isolated from one another.

In one embodiment, the at least one coaxial lead assembly is formed from a multi-layer laminate structure comprising vias and alternating dielectric layers and metal layers. The top wall and the side walls of outer conductor and the central conductor may be formed from at least first portions of one or more of the metal layers and a first set of the vias. The central conductor may be formed from at least second portions of one or more of the metal layers. The central conductor may be further formed from a second set of the vias. The dielectric structure may be formed from at least portions of one or more of the dielectric layers.

In one embodiment, the top wall may extend between upper ends of the side walls, and the central conductor is positioned between the bottom ends of the side walls.

In one embodiment, the outer conductor does not surround the central conductor at any point.

In one embodiment, the outer conductor and the dielectric structure surround at least a portion of the central conductor.

In one embodiment, the coaxial lead assembly further comprises a bottom wall that extends between the side walls such that the outer conductor surrounds at least a portion of the central conductor and the dielectric structure. The central conductor may have a contact at one end that extends toward a bottom of the coaxal lead assembly.

In one embodiment, exposed ends of the central conductor and the outer conductor comprise contacts.

In one embodiment, a plurality of leads may extend out of the housing and facilitate further electrical connections with the at least one component.

In one embodiment, the at least one coaxial lead assembly comprises two coaxial lead assemblies. The two coaxial lead assemblies may be located on opposing sides of the housing.

In one embodiment, a laminate structure may be provided on the base and surround the at least one component, wherein the at least one coaxial lead assembly is mounted on the laminate structure with the housing.

In one embodiment, the at least one component is configured to operate on a radio frequency signal that is received from the central conductor or provide a radio frequency signal that is passed by the central conductor.

In one embodiment, the at least one coaxial lead assembly is further configured to provide at least one compartment that is defined by metal walls and through which at least one conductor that is surrounded by a dielectric material extends.

In one embodiment, at least portions of the central conductor comprise a slot via. At least portions of the outer conductor may also comprise slot vias.

In one embodiment, a method for forming a module package comprises the following:
providing a base;
providing at least one component on the base; and
providing a housing over the base and encompassing the at least one component;
at least one coaxial lead assembly that extends out of the housing and facilitates electrical connections with the at least one component, the at least one coaxial lead assembly comprises a dielectric structure, a central conductor, and an outer conductor formed by a top wall extending between two side walls wherein:
   the central conductor is between the two side walls, and
   the dielectric structure resides between the central conductor and the outer conductor such that the central conductor and outer conductor isolated from one another.

In one embodiment, a communication device with the above module package is provided. The communication device may include a control system and transmit circuitry. The transmit circuitry is associated with the control system and comprise a module package for amplifying a radio frequency signal.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is an isometric view of a module package of the related art.

FIG. 2 is a top view of the module package of FIG. 1.

FIG. 3 is a side view of the module package of FIG. 1.

FIG. 4 is a cutaway view of the module package of FIG. 1.

FIG. 5 is an enlarged view of the module package of FIG. 1.

FIG. 6 illustrates the module package of FIG. 1 mounted within an opening of a printed circuit board (PCB).

FIG. 7 is a side view that illustrates a gap between the module package of FIG. 1 and the PCB.

FIG. 8 is an isometric view of a module package with a coaxial lead assembly according to one embodiment.

FIG. 9 is a top view of the module package of FIG. 8.

FIG. 10 is a side view of the module package of FIG. 8.

FIG. 11 is a cutaway view of the module package of FIG. 8.

FIG. 12 illustrates the module package of FIG. 8 mounted within an opening of a printed circuit board (PCB).

FIG. 13 is an enlarged view of the module package of FIG. 8.

FIG. 14 is a cross-sectional view of a module package with a coaxial lead assembly according to one embodiment.

FIG. 15 highlights the shielding path that is in part provided by an outer conductor of the coaxial lead assembly of FIG. 14.

FIG. 16 is an isometric view of a coaxial lead assembly according to one embodiment.

FIG. 17 is an isometric view of a module package with a coaxial lead assembly according to one embodiment, wherein the coaxial lead assembly is formed from a multilayer laminate.

FIG. 18 is an enlarged isometric view of the coaxial lead assembly according to one embodiment.

FIG. 19 is a graph of input match parameters for the module packages of the related art and with the coaxial lead assembly of the present disclosure.

FIG. 20 is a graph of loss parameters for the module packages of the related art and with the coaxial lead assembly of the present disclosure.

FIG. 21 is a cross-sectional view of the coaxial lead assembly formed from a multilayer laminate according to one embodiment.

FIG. 22 is an isometric view of the coaxial lead assembly according to one embodiment.

FIG. 23 is an isometric view of the coaxial lead assembly according to one embodiment.

FIG. 24 is an isometric view of the coaxial lead assembly according to one embodiment.

FIG. 25 is an isometric view of the coaxial lead assembly according to one embodiment.

FIG. 26 is a cross-sectional view of the coaxial lead assembly according to one embodiment.

FIG. 27 is a mobile terminal according to one embodiment.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

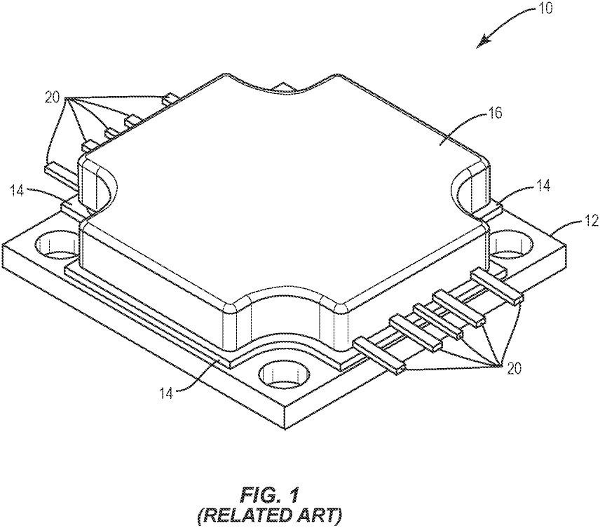

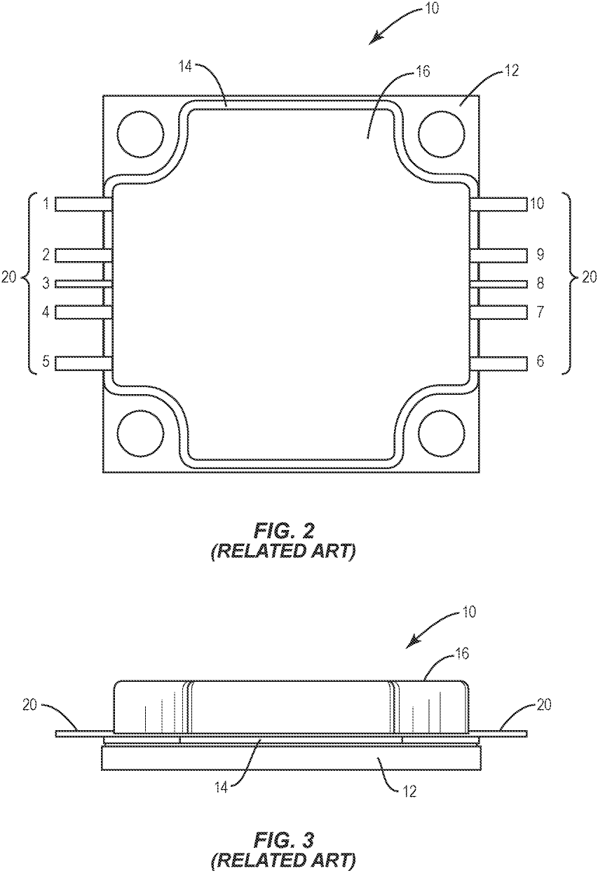

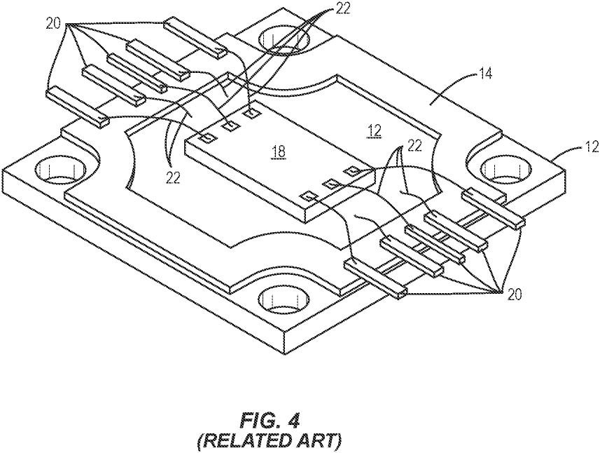

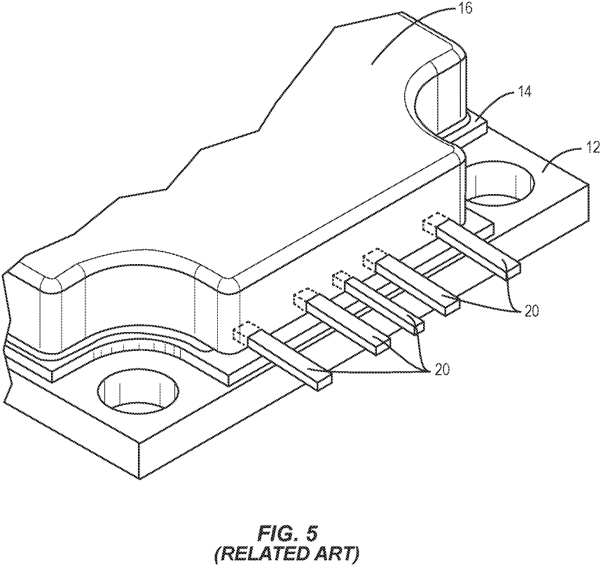

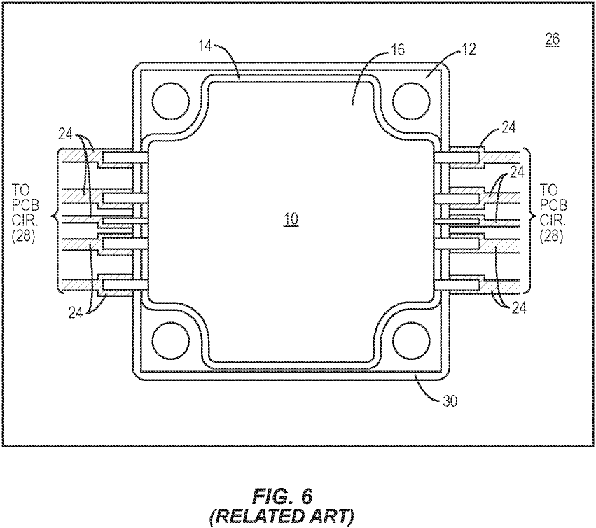

FIGS. 1-5 illustrate a conventional module package 10 that is particularly suited for radio frequency applications. The module package 10 includes a metal base 12, a multilayer laminate structure 14 over the metal base, and a housing structure 16 over the laminate structure 14. One or more electronic components 18 are typically attached to the metal base 12 and connected to leads 20 that are mounted on the laminate 14 via bond wires 22 or the like, as illustrated most clearly in FIG. 4. The housing structure 16 may be formed from an appropriate molding compound, dielectric structure, or the like, as those skilled in the art will appreciate.

The metal base 12 may be copper (Cu), copper-molybdenum (CuMO), brass, or the like, is thermally and electrically conductive, and often acts as both a ground plane and thermal dissipater or path for the components 18. The components 18 may represent integrated circuits, discrete components, die, and the like that form all or part of one or more digital or analog circuits. In certain embodiments, the circuits are radio frequency (RF) circuits that involve amplifying sensitive RF signals that may be prone to noise or degradation as well as cause interference with other signals that are being handled by the overall circuitry in which the module package 10 is being used. Certain parts of these circuits may also be formed on the laminate structure 14 in addition to being mounted directly on the base 12.

With continued reference to FIG. 4, the laminate structure 14 is a ring with a central opening that exposes the top surface of the base 12, in one embodiment. The components 18 may be mounted on the top surface of the base 12 within the central opening of the laminate structure 14. Only one component 18 is shown for clarity and conciseness. Groups of leads 20 are provided on opposing sides of the laminate structure 14, although the leads may be provided on any and/or all sides of the laminate structure 14 depending on the particular application. For the illustrated embodiment, the components 18 provide a circuit that amplifies an RF signal wherein the leads 20 may be referred to as pins and are assigned as follows.

| | |
|---|---|
| Pin 1 | VG (gate voltage) |
| Pin 2 | GND (ground) |
| Pin 3 | RF IN (RF input) |
| Pin 4 | GND (ground) |
| Pin 5 | VG (gate voltage) |
| Pin 6 | VD (drain voltage) |
| Pin 7 | GND (ground) |
| Pin 8 | RF OUT (RF output) |
| Pin 9 | GND (ground) |
| Pin 10 | VG (drain voltage) |

In this example, an RF signal is provided to the RF input (Pin 3) and amplified to provide an RF output signal at the RF output (Pin 8). Pins 2, 4, 7 and 9 are for ground while the remaining pins are for the relative DC voltages used for control and power for the module package 10, as those skilled in the art will appreciate. While this amplifier configuration is used as an example, the function or functions provided by the module may vary from application to application.

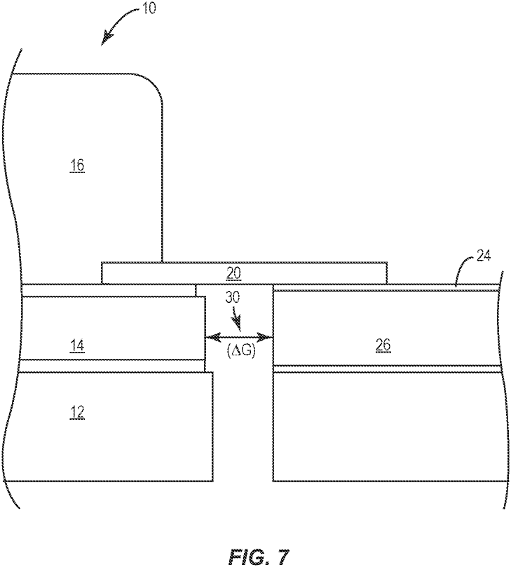

Reference is now made to FIGS. 6 and 7. In certain cases, the bottom of the leads 20 are soldered or otherwise electrically and mechanically coupled to pads 24 of a larger, multi-layer printed circuit board (PCB) 26. The pads 24 lead to various PCB circuitry 28, which is not illustrated, but is understood by those skilled in the art. The components 18 provided by the module package 10 connect to and form part of the PCB circuitry 28. The module package 10 resides in an opening in the PCB 26 wherein a gap 30 that extends around the module package 10 remains between the PCB 26 and the module package 10. The presence of the gap 30 has a negative impact on the RF performance of the overall system.

Since the leads 20 are formed of a conductive metal, such as Cu, they are mostly inductive and provide a parasitic inductance. The inductive nature of the leads 20 restricts both the operating frequency at which the module package 10 can be used as well as the bandwidth over which an acceptable package transition can be realized. To make matters worse, the parasitic inductance varies substantially based upon the gap 30 between the module package 10 and where the leads 20 land on the adjacent PCB 26. The gap 30 presents an unavoidable issue due to required mechanical tolerances. Further, the width of the gap 30, and as such the parasitic inductances associated with the leads, can vary based on where exactly the package is placed and bolted down within the assembly due to placement tolerances.

Another issue with the module package 10 is the RF power handling of the overall system, which includes the module package 10 and the PCB 26. For the module package 10, the leads 20 are provided on the laminate structure 14, which is formed from an organic substrate that has limited thermal conductivity (e.g. less than 2 W/(m*K)). As frequency and RF power increase, additional power is dissipated, and at a certain point, traces on the laminate structure 14 will delaminate. The result is a long-term reliability issue.

In the short term, the traces can get so hot that the solder on the PCB 26 where the leads 20 are attached actually reflows. The result is a catastrophic failure. Much of the issue is related to the fact that a portion of the leads is sitting in air, bridging the gap 30 between the module package 10 and the PCB 26. In this case, there are only two heat transfer mechanisms. The heat must conduct along the lead 20 or convection around the lead 20 must transfer the heat. The latter heat transfer mechanism is negligible. A better way to transfer heat across the gap 30 is desirable.

The module package 10 also presents some integration challenges. There is no direct mechanism within the module package 10 to route DC or RF from the top side of the module package 10 to the bottom side of the module package 10. The laminate structure 14 may be a two-layer board in the baseline platform, thus providing DC bias internally to both sides of the package from a single package pin is a challenge. Many system applications desire single side biasing, and it would be attractive to have a solution which supports this. In addition, since many power devices require biasing from both top and bottom, the current package platform requires designers to use redundant package pins in order to provide the bias voltages to both sides of the die. This inevitably reduces the flexibility of biasing a part (e.g. biasing stages independently becomes difficult or unfeasible). If top to bottom routing could easily be accomplished that would allow a unique supply to be used for each individual pin rather than mirroring DC pins top to bottom (e.g. with 4 pins one could have VG1, VG2, VD1, VD2 rather than just VD and VG, wherein VG is a gate voltage bias and the VD is drain voltage bias).

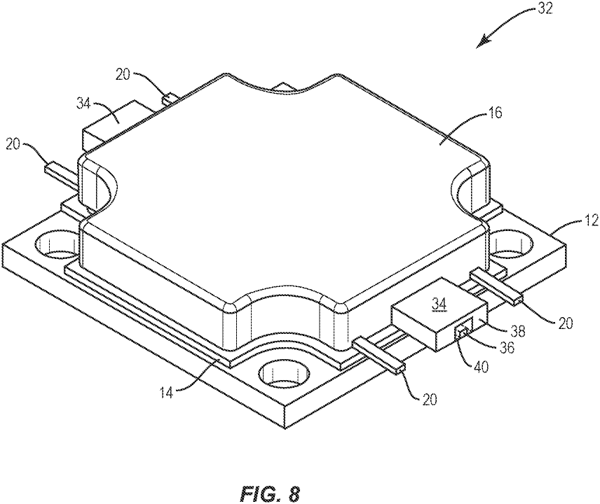

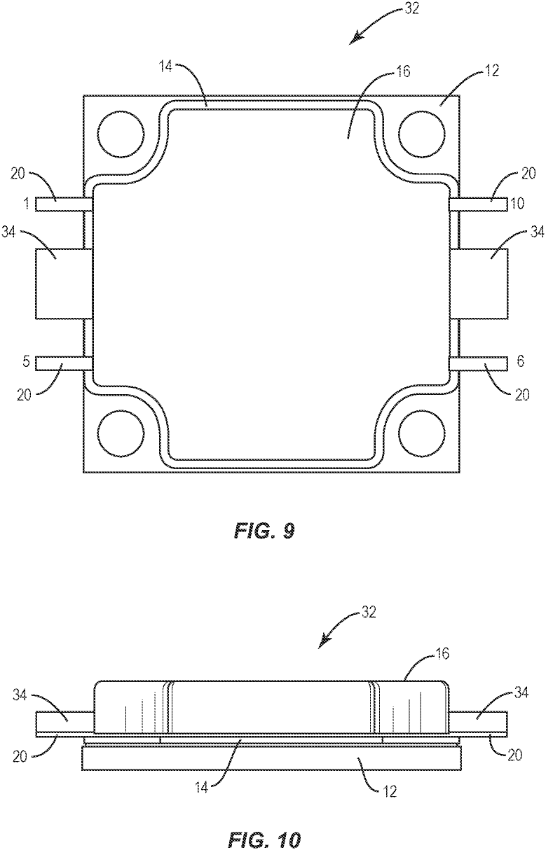

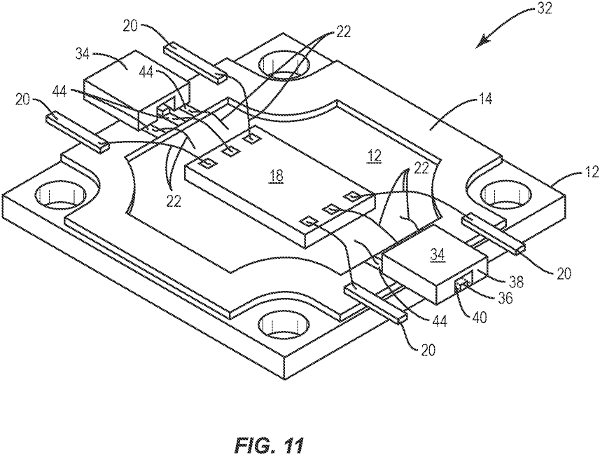

With reference now to FIGS. 8-11, the concepts of the present disclosure are described in detail using a modification of the module package 10; however, those skilled in the are will realize that these concepts are applicable to other module types and configurations. The new module package is refenced as module package 32 . Like the module package 10, the new module package 32 may include a metal base 12, a multilayer laminate structure 14 over the metal base, and a housing structure 16 over the laminate structure 14. One or more electronic components 18 are typically attached to the metal base 12 and connected to certain leads 20 that are mounted on the laminate 14 via bond wires 22 or the like, as illustrated most clearly in FIG. 11.

In the current embodiment, the three central leads 20 (RF IN/OUT, GND) of the earlier described module package 10 are effectively provided by a coaxial lead assembly 34. The coaxial lead assembly 34 provides a central conductor 36, an outer conductor 38, and a dielectric structure 40 therebetween. The outer conductor will, depending in the embodiment, either partially or completely surround the central conductor 36, as described below.

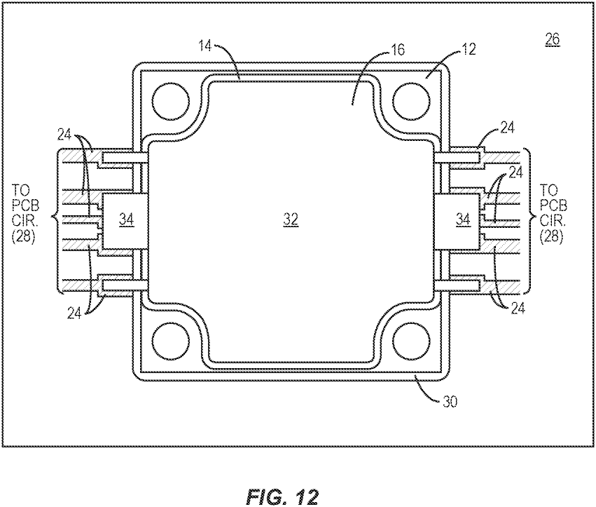

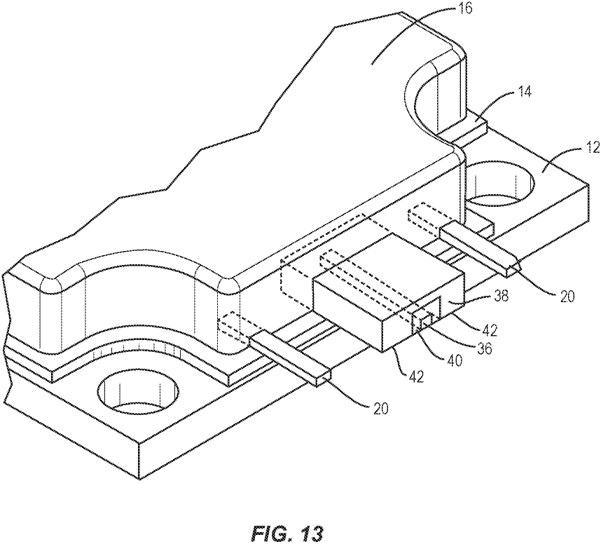

With reference to FIGS. 12 and 13, the module package 32 may be placed in the opening of the PCB 26 wherein a gap 30 is provided between the module package 32 and the PCB 26 around the periphery of the module package 32. The coaxial lead assembly 34 bridges the gap 30 and is configured such that the central conductor 36 is soldered or otherwise electrically and mechanically attached to a corresponding pad 24 of the PCB 26. Similarly, both ends 42 of the U-shaped outer conductor 38 may be soldered or otherwise electrically and mechanically attached to two pads 24 of the PCB, wherein the pad 24 for the central conductor 36 is between the two pads 24 for the outer conductor 38.

Each coaxial lead assembly 34 has a first portion within the housing structure 16 and a second portion that extends outside of the housing structure 16. Within the housing structure 16, the central conductor 36 and the outer conductor 38 are electrically and/or mechanically coupled to the laminate structure 14, with electrical connection to the components 18 and/or base 12 using bond wires 22, lead frame segments, vias, traces, or any combination thereof. Within the housing 16, the coaxial lead assembly 34 may be configured such that the central conductor 36 is soldered or otherwise electrically and mechanically attached to a corresponding laminate pad 44 of the laminate structure 14. Similarly, both ends 42 of the U-shaped outer conductor 38 may be soldered or otherwise electrically and mechanically attached to two corresponding pads 24 of the laminate structure 14, wherein the laminate pad 44 for the central conductor 36 is between the two laminate pads 44 for the outer conductor 38. In essence, the outer conductor 38 has two side walls S and a top wall T that extends between the ends of the two side walls S.

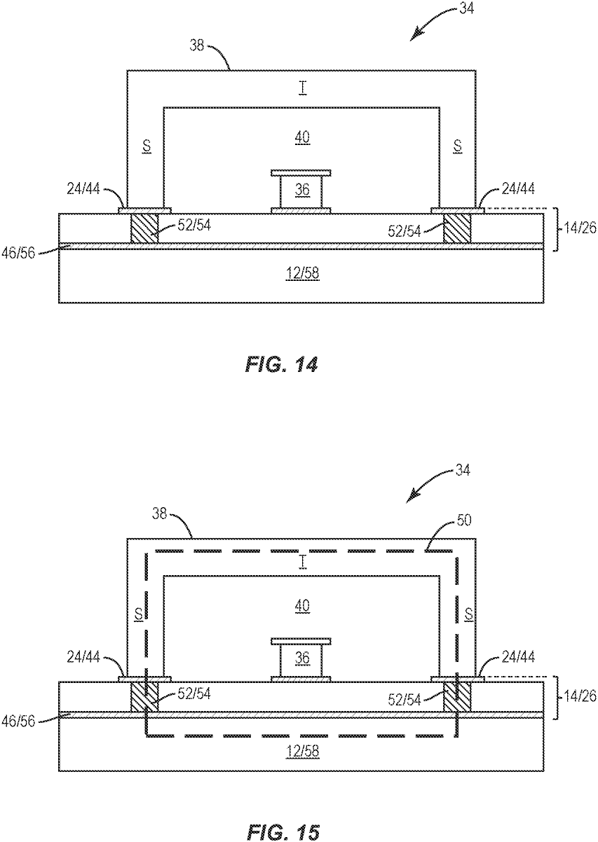

FIG. 14 provides a cross-sectional view of the coaxial lead assembly 34 of one embodiment, from two perspectives: one over the laminate structure 14 of the module package 32 and one over the PCB 26. The purpose is to illustrate how the coaxial lead assembly 34 combines ground paths in both the module package 32 and the PCB 26 to provide an outer shield that surrounds at least certain portions of the central conductor 36 to provide a coaxial structure for more effective transmission of RF or like sensitive signals between the module package 32 and the PCB 26.

The dashed line of FIG. 15 highlights the shielding path 50 that surrounds at least portion of the central conductor 36. As illustrated, the outer conductor 38 of the module package 32 provides a first segment of the shielding path 50. The remaining segments of the shielding path 50 are provided through laminate vias 52 to the ground plane layer 46 of the laminate structure 14 as well as through PCB vias 54 to the ground plane layer 56 of the PCB 26. The respective ground plane layers 46/56 are electrically and mechanically coupled to the base 12 and a PCB ground 58.

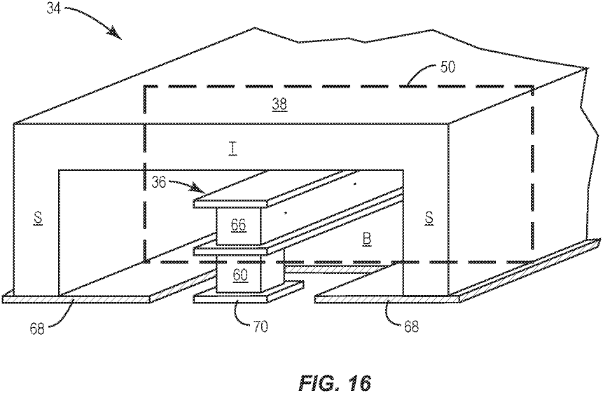

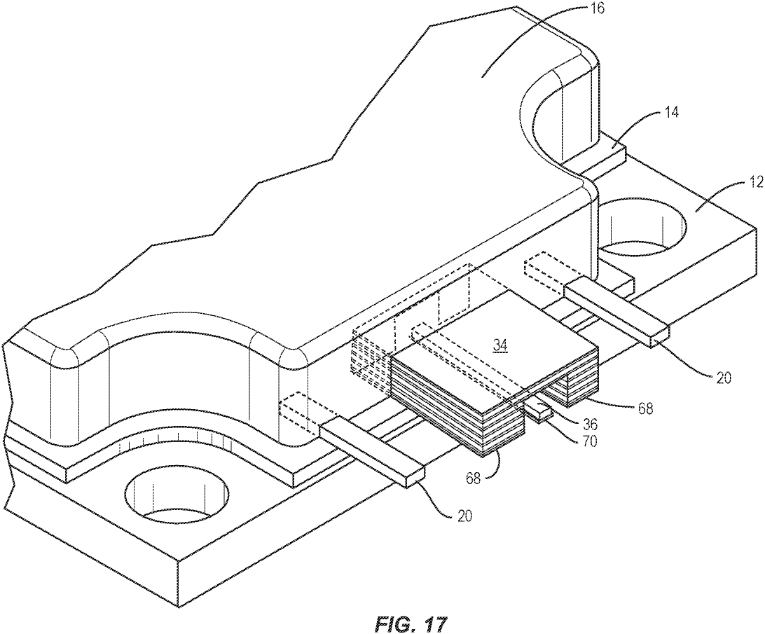

In an alternative embodiment, the entirety of the shielding path 50 is provided by the coaxial lead assembly 34. With refence to FIG. 16, the central conductor 36 is elevated to a more central location within the overall coaxial lead assembly 34, and the outer conductor 38 is formed from the top wall T, the two side walls S, and a new bottom wall B. As such, the outer conductor 38 has two side walls S and a top wall T that extends between the top ends of the two side walls S, wherein the bottom wall B extends between the bottom ends of the two side walls S. Notably, a vertical contact 60 may extend downward at or near each end of the central conductor 36 to facilitate contact with the pads 24 of the PCB 26 and the laminate pads 44 of the laminate structure 14 via a central conductor contact 70. The dielectric structure 40 is not illustrated, in order to provide better clarity for the conductor structures.

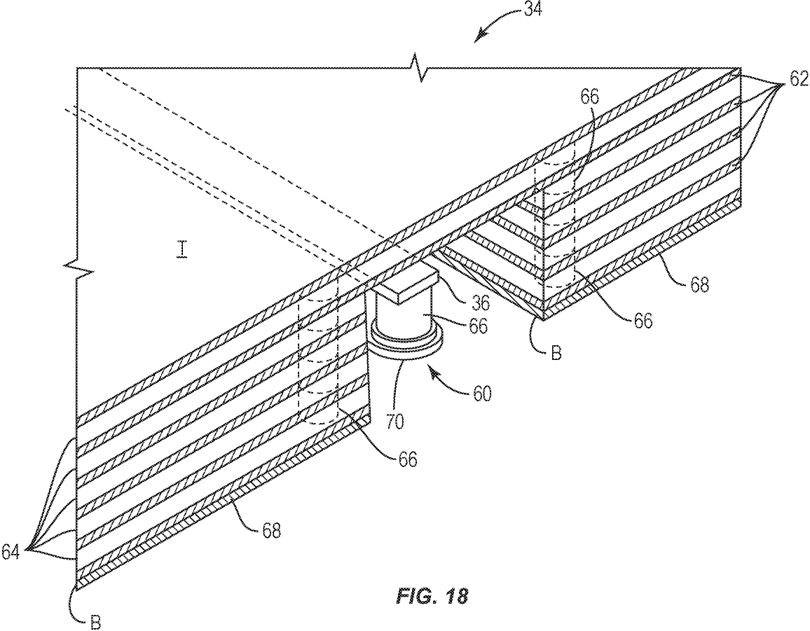

In select embodiments, the central conductor 36 may be formed from a traditional lead structure, lead frame, or like structure or material. The outer conductor 38, as well as the central conductor 36 may be formed from precast conductive structures, 3D printed structures, or the like. As illustrated in FIGS. 17 and 18, and as described further below, the module package 32 may alternatively be formed from a multilayer laminate that employs alternating metal layers 62, which are appropriately patterned, and dielectric layers 64 in combination with selectively placed vias 66 to provide embodiments equivalent to those provided above. FIG. 17 corresponds to the coaxial lead assembly 34 of FIG. 14, wherein the outer conductor 38 is U-shaped and the central conductor 36 is placed lower in the overall coaxial lead assembly 34. One or more of the upper metal layers 62 provides the top wall T, and groups of vias 66 that extend between the metal layers 62 and portions of the intermediate metal layers 62 form the side walls S. Note that a section of the multi-layer laminate around the central conductor 36 is not shown to better illustrate the central conductor 36 within the assembly. In this area, the metal layers 62 will be removed while the dielectric layers 64 may remain in the region between the central conductor 36 and the outer conductor 38 to provide structural integrity for the central conductor 36 and facilitate heat transfer from the module assembly 34 to the PCB 26.

FIG. 18 corresponds to the coaxial lead assembly 34 of FIG. 16 wherein the central conductor 36 is more centralized and the outer conductor 38 completely surrounds at least certain portions of the central conductor 36 due to the presence of a bottom wall B. One or more of the upper metal layers 62 provide the top wall T, one or more bottom layers provide the bottom wall B, and groups of vias 66 that extend between the metal layers 62 and portions of the intermediate metal layers 62 form the side walls S. For both embodiments, the outer conductor contacts 68 and the central conductor contacts 70 may be provided by or on the bottom metal layer 62 of the multilayer laminate. Note that a section of the multi-layer laminate around the central conductor 36 is not shown to better illustrate the central conductor 36 within the assembly. In this area, the metal layers 62 will be removed while the dielectric layers 64 may remain in the region below the central conductor 36 and between the central conductor 36 and the outer conductor 38 to provide structural integrity for the central conductor 36 and facilitate heat transfer from the module assembly 34 to the PCB 26.

There are multiple advantages of using the coaxial lead assembly 34 to provide an outer conductor 38 that wraps around dielectric structure 40 contacts and extends to opposing sets of PCB pads 24 and laminate pads 44 of the PCB 26 and laminate structure 14 of the module package 32. The full encapsulation of all or portions of the central conductor 36 creates a coaxial transverse electromagnetic (TEM) mode that extends from the PCB 26 to the interior of the module package 32. When the RF wave travels between the PCB 26 and module package 32, the wave crosses the (air) gap 30 between the two entities. The RF transmission mode is quasi-TEM in this section and has a very similar field pattern to a coaxial mode, which lowers the impact of the gap 30 on the transition from the PCB 26 to the module package 32. Additionally, by having an outer conductor 38 for shielding the RF from adjacent traces or metal objects, the effective coaxial lead transition should have high tolerance to variations of the size of the gap 30 between the PCB 26 and module package 32. This variation in the gap is further referenced as a delta-gap (ΔG). Furthermore, there is now a dielectric structure 40 between the central conductor 36 and a nearby metal ground plane to further improve the transfer of heat from the module package 32 to the PCB 26. The heat can now be transferred though the dielectric structure 40 instead of just though the leads 20 and being almost completely blocked by the (air) gap 30.

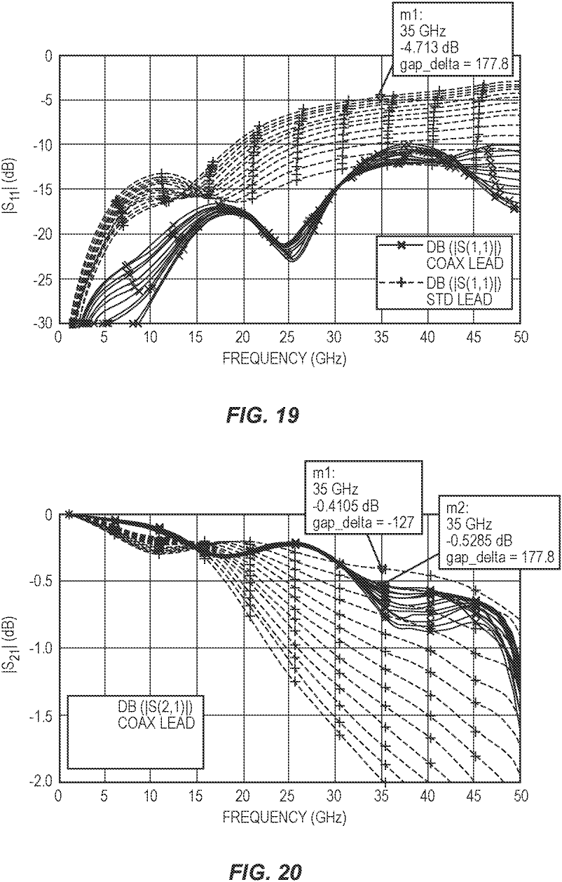

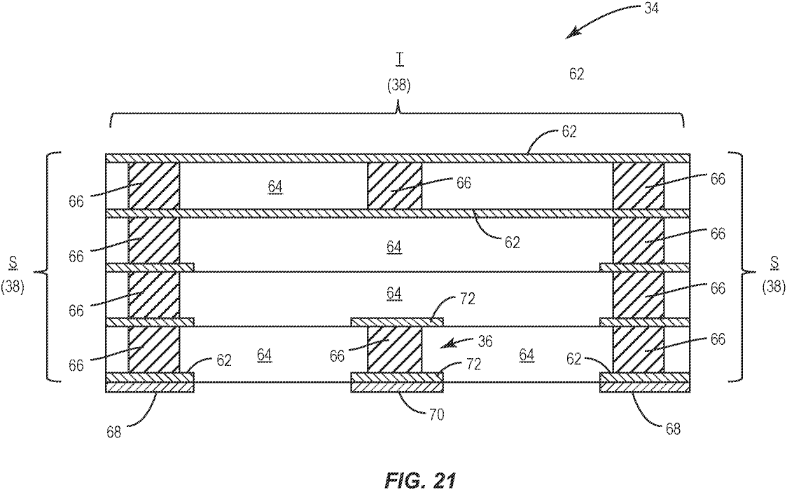

Two simulations were completed to compare the coaxial lead transition provided by the coaxial lead assembly 34 of module package 32 to the standard module package 10Error! Reference source not found.. The S-parameters for input match and loss are shown in FIG. 19 and FIG. 20, respectively. A -127 um value is no gap, while 177.8 um is a 12 mil gap for the gap 30 between the PCB 26 and module packages 10/34. Assume that the gap value of 0um, or 5mil between the PCB 26 and the module packages 10/34 is the nominal distance used when designing the package transition. The dashed lines represent the variations in S-parameters as the gap 30 transitions from no gap to a 12 mil gap for the module package 10 (that does not have the coaxial lead assembly 34) while the solid lines represent the variations over the same range for the module package 32 with the coaxial lead assembly 34. While neither is optimally tuned for a particular frequency range, it is evident from the simulations that the module package 32 with the coaxial lead assembly 34 demonstrates significantly less performance variation as the width of the gap 30 changes than that for the module package 10. Major variations only start occurring above ~35 GHz for the coaxial lead assembly 34 versus <20 GHz for the standard lead 20. The S21 grouping over the swept gap is very tight from 0-30 GHz. Of note, the coaxial lead assembly 34 has lower loss for higher gap values; the lowest loss at 35 GHz occurs with the highest simulated gap of 12mil.

The following description highlights a few of the many possible variants envisioned for the coaxial lead assembly 34 that is formed from a multilayer laminate. FIG. 21 is a cross-section showing the alternating metal layers 62 and dielectric layers 64 as well as the how the top wall T and side walls S are formed with the pattered metal layers 62 and the and vias 66. Note that the top two metal layers 62 are connected by vias 66 to provide a double layered top wall T. The central conductor 36 is located at the bottom of the coaxial lead assembly 34 and is formed from a row of individual vias 66 or a slot via (that extends into the figure) that extend between two metal traces 72. Outer metal contacts 68 and a central conductor contact 70 may be provided at each end of the side walls S and the central conductor 36.

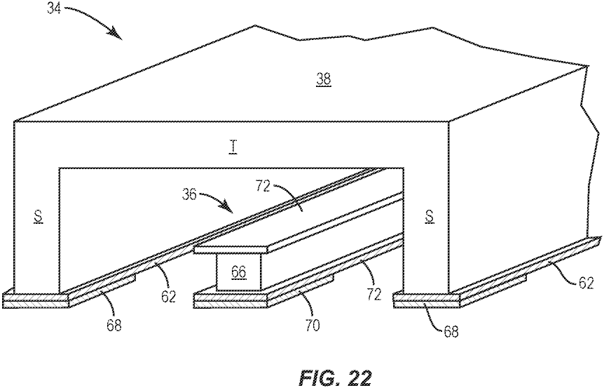

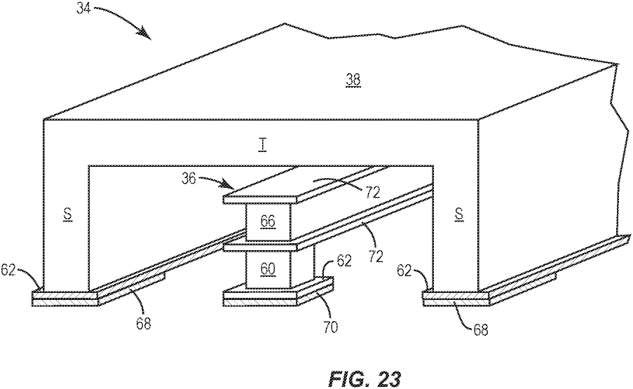

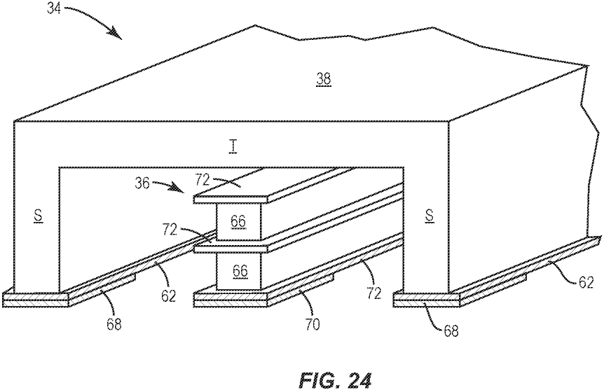

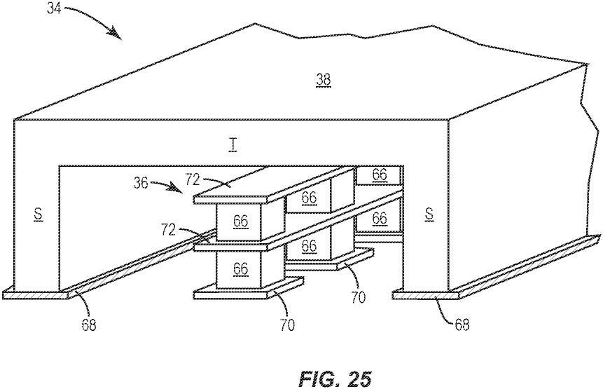

FIG. 22 provides an isometric view wherein the multilayer details of the outer conductor 38 are hidden. An elongated slot 66 via between metal traces from the metal layers 62 forms the central conductor 36. FIG. 23 illustrates a version wherein the central conductor 36 is elevated and employs a slot via 66 and portions of metal layers 62 to provide the central conductor 36, which terminates with a central conductor contact 70 through the vertical contact 60 at the same level as the outer conductor contacts 68 of the side walls S. FIG. 24 provides a similar configuration with the main difference being the use of two vertically stacked slot vias 66 to provide a larger central conductor 36. In any of these configurations, the slot vias 66 may be replaced with traditional vias 66 that are aligned in a series, as illustrated in FIG. 25.

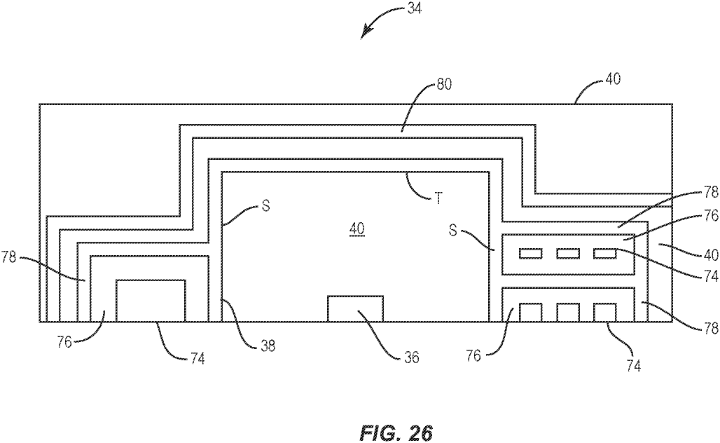

The coaxial lead assembly 34 may be expanded to provide additional conductor structures 74, which may be provide additional compartments 76, as illustrated in FIG. 26. The compartments 76 may be stacked beside or over one another and may contain one more multiple conductor structures 74. The compartments may share conductive walls 78 with each other and/or the outer conductor 38. Further, additional conductor structures 80 may be provided outside and/or above the compartments 76 and outer conductor 38. The coaxial lead assembly 34 of FIG. 26 may also be implemented with multilayer laminate structures, printed structures, and the like, as detailed above. These additional structures may all have routing structures that lead to contacts for connections with the laminate structure 14 of the module package 32 and/or the PCB 26. Such configurations are particularly beneficial for routing DC (direct current) lines above and/or around the central conductor 36 and/or the outer conductor 38 between the module package 32 and the PCB 26 via the coaxial lead assembly 34.

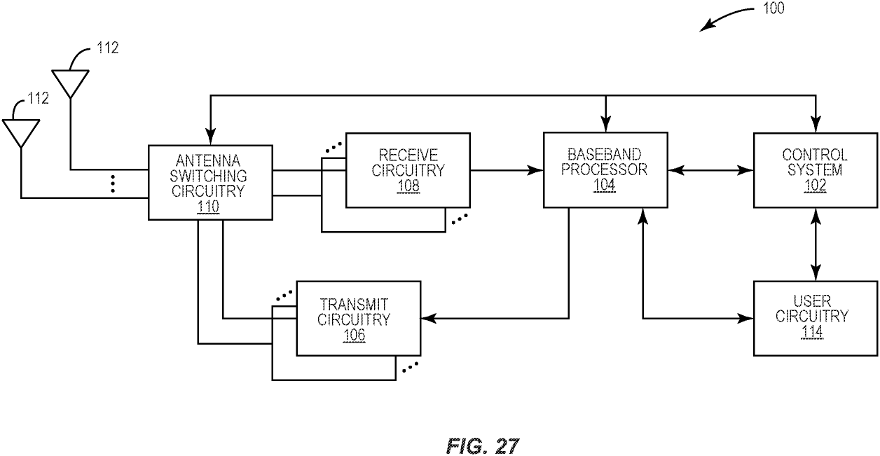

With reference to FIG. 27, the concepts described above may be implemented in various types of user elements 100, such as mobile terminals, smart watches, tablets, computers, navigation devices, access points, and like wireless communication devices that support wireless communications, such as cellular, wireless local area network (WLAN), Bluetooth, and near field communications. The user elements 100 will generally include a control system 102, a baseband processor 104, transmit circuitry 106, receive circuitry 108, antenna switching circuitry 110, multiple antennas 112, and user interface circuitry 112. In a non-limiting example, the control system 102 can be a field-programmable gate array (FPGA) or an application-specific integrated circuit (ASIC). In this regard, the control system 102 may include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter of the receive circuitry 108 cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed on greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 40 through the antenna switching circuitry 110 to the antennas 112. The transmit circuitry 106 may include a module package 32, wherein the components 18 are RF amplifiers that amplify a signal received via the central conductor 36 of one coaxial lead assembly 34 and provide an amplified signal via the central conductor 36 of another coaxial lead assembly 34. The multiple antennas 112 and the replicated transmit and receive circuitries 106, 108 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A module package comprising:
a base;
at least one component on the base; and
a housing over the base and encompassing the at least one component;
at least one coaxial lead assembly that extends out of the housing and facilitates electrical connections with the at least one component, wherein the at least one coaxial lead assembly comprises a dielectric structure, a central conductor, and an outer conductor formed by a top wall extending between two side walls wherein:
the central conductor is between the two side walls, and
the dielectric structure resides between the central conductor and the outer conductor such that the central conductor and outer conductor are isolated from one another.

2. The module package of claim 1 wherein the at least one coaxial lead assembly is formed from a multi-layer laminate structure comprising vias and alternating dielectric layers and metal layers, wherein:
the top wall and the two side walls of the outer conductor are formed from at least first portions of one or more of the metal layers and a first set of the vias; and
the central conductor is formed from at least second portions of one or more of the metal layers.

3. The module package of claim 2 wherein the central conductor is further formed from a second set of vias.

4. The module package of claim 2 wherein the dielectric structure is formed from at least portions of one or more of the dielectric layers.

5. The module package of claim 2 wherein the top wall extends between upper ends of the side walls and the central conductor is positioned between bottom ends of the two side walls.

6. The module package of claim 2 wherein the outer conductor does not surround the central conductor at any point.

7. The module package of claim 2 wherein the outer conductor and the dielectric structure surround at least a portion of the central conductor.

8. The module package of claim 2 wherein the at least one coaxial lead assembly further comprises a bottom wall that extends between the two side walls such that the outer conductor surrounds at least a portion of the central conductor and the dielectric structure.

9. The module package of claim 8 wherein the central conductor has a contact at one end that extends toward a bottom of the at least one coaxial lead assembly.

10. The module package of claim 1 wherein exposed ends of the central conductor and the outer conductor comprise contacts.

11. The module package of claim 1 further comprising a plurality of leads that extend out of the housing and facilitate further electrical connections with the at least one component.

12. The module package of claim 1 wherein the at least one coaxial lead assembly comprises two coaxial lead assemblies.

13. The module package of claim 12 wherein the two coaxial lead assemblies are located on opposing sides of the housing.

14. The module package of claim 1 further comprising a laminate structure on the base and surrounding the at least one component wherein the at least one coaxial lead assembly is mounted on the laminate structure with the housing.

15. The module package of claim 1 wherein the at least one component is configured to operate on a radio frequency signal that is received from the central conductor or provide a radio frequency signal that is passed by the central conductor.

16. The module package of claim 1 wherein the at least one coaxial lead assembly is further configured to provide at least one compartment that is defined by metal walls and through which at least one conductor that is surrounded by a dielectric material extends.

17. The module package of claim 1 wherein at least portions of the central conductor comprise a slot via.

18. The module package of claim 17 wherein at least portions of the outer conductor comprise slot vias.

19. A method for forming a module package comprising:
providing a base;
providing at least one component on the base; and
providing a housing over the base and encompassing the at least one component;
at least one coaxial lead assembly that extends out of the housing and facilitates electrical connections with the at least one component, the at least one coaxial lead assembly comprises a dielectric structure, a central conductor, and an outer conductor formed by a top wall extending between two side walls wherein:
the central conductor is between the two side walls, and
the dielectric structure resides between the central conductor and the outer conductor such that the central conductor and outer conductor are isolated from one another.

20. A communication device comprising:
a control system;
transmit circuitry associated with the control system and comprising a module package for amplifying a radio frequency signal, the module package comprising:
a base;
at least one component on the base;
a housing over the base and encompassing the at least one component; and
at least one coaxial lead assembly that extends out of the housing and facilitates electrical connections with the at least one component, the at least one coaxial lead assembly comprises a dielectric structure, a central conductor, and an outer conductor formed by a top wall extending between two side walls wherein:
the central conductor is between the two side walls, and
the dielectric structure resides between the central conductor and the outer conductor such that the central conductor and outer conductor are isolated from one another.
